(19) United States
(12) Patent Application Publication
(10) Pub. No.: US 2026/0164997 A1
(43) Pub. Date: Jun. 11, 2026

(54) DISPLAY DEVICE AND DISPLAY PANEL

(71) Applicant: LG Display Co., Ltd., Seoul (KR)

(72) Inventors: Sunmi Lee, Paju-si (KR); Yong-Il Kim, Paju-si (KR); Bokyoung Lee, Paju-si (KR); KwanSik Yun, Paju-si (KR)

(21) Appl. No.: 19/376,883

(22) Filed: Oct. 31, 2025

(30) Foreign Application Priority Data
Dec. 6, 2024 (KR) 10-2024-0180808

(51) Int. Cl. H10K 59/80; H10K 59/12; H10K 59/121; H10K 59/126; H10K 59/35; H10K 59/65

(52) U.S. Cl. CPC H10K 59/873; H10K 59/1201; H10K 59/1213; H10K 59/126; H10K 59/352; H10K 59/65

(57) ABSTRACT

A display device includes a display panel in which an optical electronic device is disposed within a display area, wherein the display area includes a normal area in which a plurality of subpixels including an emission layer are disposed, a through-hole in which the optical electronic device is located, and a surrounding area in which one or more emission layer disconnection patterns are formed between the normal area and the through-hole.

### CROSS REFERENCE TO RELATED APPLICATION

Pursuant to 35 U.S.C. § 119(a), this application claims the benefit of an earlier filing date and right of priority to Korean Patent Application No. 10-2024-0180808, filed in the Republic of Korea on Dec. 6, 2024, the entire disclosure of which is hereby expressly incorporated by reference for all purposes as if fully set forth herein.

### TECHNICAL FIELD

The present disclosure relates to a display device and a display panel, and more specifically, to a display device and a display panel capable of effectively forming an emission layer disconnection pattern for reducing, minimizing, or preventing moisture from penetrating through a through-hole where an optical electronic device is located.

### BACKGROUND

With the development of information technology, many related technologies have been developed in the field of display devices for visually displaying information, such as text, images, video, or graphical data. A display device is an output device that converts electrical signals into visible light patterns, typically using an array of pixels composed of subpixels.

### SUMMARY

As examples of display devices for displaying images using digital data, there are liquid crystal displays (LCD) using liquid crystals and organic light emitting displays (OLED) using organic light emitting diodes. Among display devices, the organic light emitting display device utilizes self-luminous light emitting diodes, which provide fast response speeds and have advantages in contrast ratio, luminous efficiency, brightness, and viewing angle. In this case, the light emitting diodes can be implemented with organic materials. The organic light emitting display device may include organic light emitting diodes arranged in each of a plurality of subpixels disposed on a display panel, and may control the brightness of each subpixel by controlling a voltage flowing to the organic light emitting diodes to emit light, thereby displaying images.

As technology advances, these display devices can provide image-capturing functions and various sensing functions in addition to the function of displaying images. To this end, the display device may be equipped with optical electronic devices or elements (also referred to as light receiving devices or sensors) such as cameras and sensing sensors. Since an optical electronic device is involved to receive light from the front of the display device, the optical electronic device is typically installed in a place where light reception is advantageous. Therefore, research is being conducted to form a through-hole in the active area where the subpixel is formed and to place the optical electronic device inside the through-hole. In this way, the configuration where there is a through-hole for placing an optical electronic device inside the active area may be referred to as a hole-in active area (HiAA).

However, if moisture enters the through-hole where the optical electronic device is located, there is an issue that the performance of the light emitting element constituting the subpixel decreases. Accordingly, the inventors of the present disclosure recognized the limitations mentioned above and other limitations associated with the related art, and conducted various experiments to implement a display device and a display panel capable of effectively forming an emission layer disconnection pattern for preventing or reducing moisture from flowing in through the through-hole where an optical electronic device is located.

Examples of the present disclosure may provide a display device and a display panel having an emission layer disconnection pattern formed to effectively block or reduce moisture flowing in from the side and bottom through a through-hole. Examples of the present disclosure may provide a display device and a display panel capable of effectively blocking or reducing moisture flowing in through a through-hole even in the case of a display panel in which flexible operation is performed.

In one aspect, a display device according to examples of the present disclosure may include a display panel in which an optical electronic device is disposed within a display area, wherein the display area includes a normal area in which a plurality of subpixels including an emission layer are disposed, a through-hole in which the optical electronic device is located, and a surrounding area in which one or more emission layer disconnection patterns are formed between the normal area and the through-hole.

In another aspect, a display panel according to examples of the present disclosure may include a normal area in which a plurality of subpixels including an emission layer are disposed, a through-hole in which an optical electronic device is located, and a surrounding area in which one or more emission layer disconnection patterns are formed between the normal area and the through-hole.

In yet another aspect, a display device according to examples of the present disclosure may include a display panel in which an optical electronic device is disposed within a display area, wherein the display area includes a normal area in which a plurality of subpixels including an emission layer are disposed, a through-hole in which the optical electronic device is located, and a surrounding area between the normal area and the through-hole, and wherein the emission layer is physically divided into two parts spaced apart from each other in the surrounding area.

According to examples of the present disclosure, it is possible to effectively form an emission layer disconnection pattern capable of reducing, minimizing, or preventing moisture from entering through a through-hole where an optical electronic device is located. According to examples of the present disclosure, it is possible to implement a process optimization during formation of an emission layer disconnection pattern formed to effectively block moisture flowing in from the side and bottom through a through-hole. According to examples of the present disclosure, it is possible to effectively reduce or block moisture flowing in through a through-hole even in the case of a display panel in which flexible operation is performed.

However, the effects of the present disclosure are not limited to the foregoing aspects, and other effects will be apparent to one of ordinary skill in the art from the following detailed description. It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that may be included to provide a further understanding of the present disclosure and may be incorporated in and constitute a part of the present disclosure, illustrate examples of the present disclosure, and together with the detailed description serve to explain various principles of the present disclosure.

FIG. 1 schematically illustrates a system diagram of a display device according to an example of the present disclosure.

FIG. 2 illustrates an equivalent circuit of a subpixel in a display panel according to an example of the present disclosure.

FIG. 3 illustrates the arrangement of subpixels in three areas included in a display area in a display panel according to an example of the present disclosure.

FIG. 4 illustrates a cross-section of a display area in a display panel according to an example of the present disclosure.

FIG. 5 illustrates a planar structure of an optical area in a display panel according to an example of the present disclosure.

FIG. 6 illustrates a cross-section of a normal area and an optical area in a display panel according to an example of the present disclosure.

FIGS. 7-13 are cross-sectional views sequentially illustrating a manufacturing process of a display panel according to an example of the present disclosure.

Throughout the accompanying drawings and the detailed description, unless otherwise stated, like drawing reference numerals should be understood as referring to like elements, features, and structures. The relative size and depiction of these elements may be exaggerated for clarity, illustration, and/or convenience.

### DETAILED DESCRIPTION

Hereinafter, examples of the present disclosure will be described in detail with reference to the accompanying drawings. In the following description of the examples of the present disclosure, reference will be made to the accompanying drawings in which like reference numerals and signs designate the same or like components even when they are shown in different accompanying drawings from one another. Further, in the following description of the examples of the present disclosure, detailed descriptions of well-known functions and components incorporated herein will be omitted when it is determined that such description may obscure an important point of the present disclosure. The progression of any processing steps and/or operations described herein is provided as an example; however, the sequence of steps and/or operations is not limited to that set forth herein and may be changed as is known in the art, with the exception of steps and/or operations necessarily occurring in a particular order, which will be clearly described as such if the particular order to the steps and/r operations is pertinent to realizing the technical effect. Names of the respective elements used in the following explanations are selected only for convenience of writing the specification and, thus, may be different from those used in actual products.

Advantages and features of the present disclosure, and implementation methods thereof will be clarified through the following examples described with reference to the accompanying drawings. The present disclosure may, however, be embodied in different forms and should not be construed as limited to the examples set forth herein. Rather, these examples are provided so that the present disclosure may be sufficiently thorough and complete to assist those skilled in the art to fully understand the scope of the present disclosure. Further, the scope of the present disclosure is only defined by the accompanying claims. Any implementation described herein as an “example” is not necessarily to be construed as preferred or advantageous over other implementations.

The shapes, sizes, ratios, angles, numbers, and the like, which are illustrated in the accompanying drawings to describe various examples of the present disclosure are merely illustrative. Therefore, the present disclosure is not limited to the illustrations in the drawings. The same or similar elements are designated by the same reference numerals throughout the specification unless otherwise specified. In the following description where the detailed description of the relevant known function or configuration may unnecessarily obscure an important point of the present disclosure, a detailed description of such known function of configuration may be omitted.

Terms, such as “first”, “second”, “A”, “B”, “(A)”, or “(B)”, may be used herein to describe elements of the present disclosure. Each of these terms is not used to define essence, order, sequence, or number of elements, etc., but is used merely to distinguish the corresponding element from other elements.

The terms such as “including”, “having”, “containing”, “constituting”, “make up of”, and “formed of” used herein are generally intended to allow other components to be added unless the terms are used with a more limiting term such as “only”. As used herein, singular forms are intended to include plural forms unless the context clearly indicates otherwise.

If a component is stated to be “connected,” “coupled,” or “attached” to another component, that component may be connected, coupled, or attached directly to that other component, but it should be understood that other components may be interposed between each component that may be connected, coupled, or attached indirectly, without any specific description.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless a more limiting term such as “directly” or “immediately” is used together.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

The term “at least one” should be understood as including any and all combinations of one or more of the associated listed items. For example, the meaning of “at least one of a first element, a second element, or a third element” encompasses the combination of all three listed elements, combinations of any two of the three elements, as well as each individual element, the first element, the second element, or the third element.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Features of various examples of the present disclosure may be partially or overall coupled to or combined with each other, and may be variously inter-operated with each other and driven technically as those skilled in the art can sufficiently understand. Examples of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example examples belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various examples of the present disclosure will be described in detail with reference to the accompanying drawings.

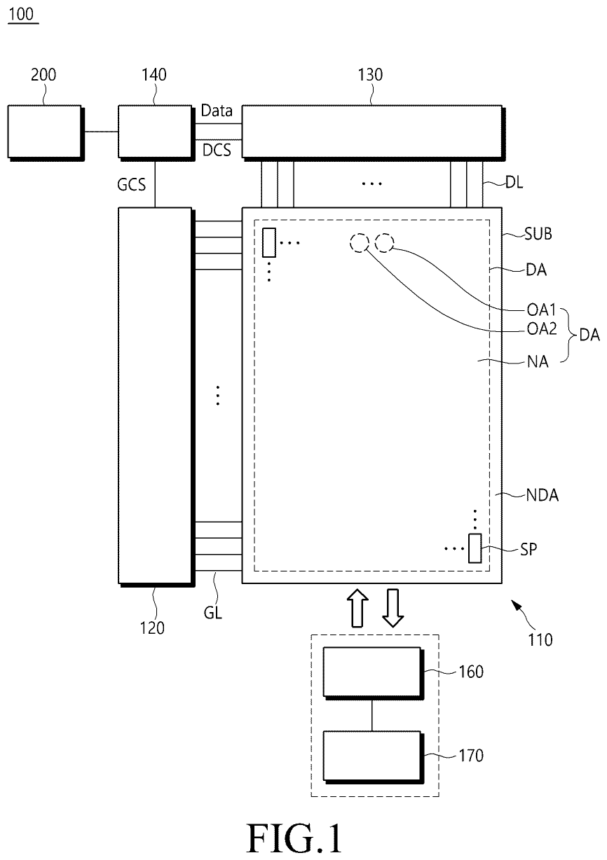

FIG. 1 schematically illustrates a system diagram of a display device 100 according to examples of the present disclosure.

Referring to FIG. 1, the display device 100 according to examples of the present disclosure may include a display panel 110 that displays an image and one or more optical electronic devices (not shown). The display panel 110 may include a display area DA where an image is displayed and a non-display area NDA where an image is not displayed. In this case, the display area DA may be referred to as an active area. A plurality of subpixels may be arranged in the display area DA, and various signal lines for driving the plurality of subpixels may be arranged. The non-display area NDA may be an area outside the display area DA. Various signal lines may be arranged in the non-display area NDA, and various driving circuits may be connected thereto. The non-display area NDA may be bent so as not to be visible from the front, or may be covered by a case (not shown). The non-display area NDA may be also referred to as a bezel or a bezel area.

In the display device 100 according to the examples of the present disclosure, one or more optical electronic devices may be electronic components located below (e.g., opposite of the viewing surface) the display panel 110. Light may enter the front side (e.g., viewing surface) of the display panel 110, pass through the display panel 110, and be transmitted to one or more optical electronic devices positioned below (e.g., opposite of the viewing surface) the display panel 110. The one or more optical electronic devices may be devices that receive light passing through the display panel 110 and perform a predetermined function according to the received light. For example, the one or more optical electronic devices may include one or more of a photographing device such as a camera (or image sensor), a detection sensor such as a proximity sensor, and an illuminance sensor, etc., but the present disclosure is not limited thereto.

In the display panel 110 according to the examples of the present disclosure, the display area DA may include a normal area NA and one or more optical areas OA1 and OA2. The one or more optical areas OA1 and OA2 may be areas overlapping with one or more optical electronic devices. The display area DA may include a normal area NA and a first optical area OA1. Here, at least a portion of the first optical area OA1 may overlap with a first optical electronic device.

In the display device 100 according to the examples of the present disclosure, if the first optical electronic device that is not exposed to the outside and is hidden under the display panel 110 is a camera, the display device 100 according to the examples of the present disclosure may be referred to as a display to which an under-display camera (UDC) technology is applied. Accordingly, in the case of the display device 100 according to the examples of the present disclosure, since a notch or camera hole for camera exposure does not need to be formed in the display panel 110, the area of the display area DA may not decrease. Accordingly, since a notch or camera hole for camera exposure does not need to be formed in the display panel 110, the size of the bezel area can be reduced, and design constraints may be eliminated, thereby increasing the degree of freedom in design.

In the display device 100 according to the examples of the present disclosure, even though one or more optical electronic devices are hidden and positioned behind the display panel 110, one or more optical electronic devices is involved to normally receive light and normally perform a corresponding function. In addition, in the display device 100 according to the examples of the present disclosure, even though one or more optical electronic devices are positioned hidden behind the display panel 110 and overlap with the display area DA, normal image display may be possible in one or more optical areas OA1 and OA2 overlapping with one or more optical electronic devices 11 in the display area DA.

In addition, the display device 100 according to the examples of the present disclosure may include the display panel 110 and a display driving circuit as components for image display. The display driving circuit may include a gate driving circuit 120, a data driving circuit 130, and a display controller 140 as a circuit for driving the display panel 110.

The display panel 110 may include a substrate SUB and a plurality of subpixels SP arranged on the substrate SUB. In addition, the display panel 110 may further include various types of signal lines in order to drive the plurality of subpixels SP. The display device 100 according to the examples of the present disclosure may be a liquid crystal display device, or may be a self-luminous display device in which the display panel 110 emits light by itself. In the case that the display device 100 according to the examples of the present disclosure is a self-luminous display device, each of the plurality of subpixels SP may include a light emitting element. The display device 100 according to the examples of the present disclosure may be an organic light emitting display device in which the light emitting element is implemented as an organic light emitting diode (OLED). For another example, the display device 100 according to the examples of the present disclosure may be an inorganic light emitting display device in which the light emitting element is implemented as an inorganic-based light emitting diode. The display device 100 according to the examples of the present disclosure may be a quantum dot display device in which the light emitting element is implemented as a quantum dot, which is a semiconductor crystal that emits light by itself. The structure of each of the plurality of subpixels SP may vary depending on the type of the display device 100. For example, if the display device 100 is a self-luminous display device in which the subpixels SP emit light by themselves, each subpixel SP may include a light emitting element that emits light by itself, one or more transistors, and one or more capacitors.

Various types of signal lines may include a plurality of data lines DL that transmit data signals (also referred to as data voltages or image signals) and a plurality of gate lines GL that transmit gate signals (also referred to as scan signals). The plurality of data lines DL and the plurality of gate lines GL may intersect each other. Each of the plurality of data lines DL may be arranged while extending in a first direction. Each of the plurality of gate lines GL may be arranged while extending in a second direction. Here, the first direction may be a column direction and the second direction may be a row direction. Alternatively, the first direction may be a row direction and the second direction may be a column direction. For convenience of description, described below is an example in which each of the plurality of data lines DL is disposed in the column direction, and each of the plurality of gate lines GL is disposed in the row direction, but the present disclosure is not limited thereto. The data driving circuit 130 may be a circuit for driving the plurality of data lines DL, and may output data signals to the plurality of data lines DL. The gate driving circuit 120 may be a circuit for driving the plurality of gate lines GL, and may output gate signals to the plurality of gate lines GL.

The display controller 140 is a device for controlling the data driving circuit 130 and the gate driving circuit 120, and may control the driving timing for a plurality of data lines DL and the driving timing for a plurality of gate lines GL. The display controller 140 may supply a data driving control signal DCS to the data driving circuit 130 to control the data driving circuit 130, and may supply a gate driving control signal GCS to the gate driving circuit 120 to control the gate driving circuit 120. The display controller 140 may receive input image data from a host system 200, and may supply image data Data to the data driving circuit 130 based on the input image data.

The data driving circuit 130 may supply data signals to a plurality of data lines DL according to the driving timing control of the display controller 140. The data driving circuit 130 may receive image data Data in digital form from the display controller 140, convert the received image data Data into data signals in analog form, and output the converted data signals to a plurality of data lines DL.

The gate driving circuit 120 may supply gate signals to a plurality of gate lines GL according to the timing control of the display controller 140. The gate driving circuit 120 may receive a first gate voltage corresponding to a turn-on level voltage and a second gate voltage corresponding to a turn-off level voltage together with various gate driving control signals GCS, generate gate signals (e.g., scan signals or emission control signals), and supply the generated gate signals to a plurality of gate lines GL. For example, the data driving circuit 130 may be connected to the display panel 110 in a tape automated bonding (TAB) manner, connected to a bonding pad of the display panel 110 in a chip-on-glass (COG) or chip-on-panel (COP) manner, or implemented in a chip-on-film (COF) manner and connected to the display panel 110.

The gate driving circuit 120 may be connected to the display panel 110 by a tape automated bonding (TAB) method, connected to a bonding pad of the display panel 110 by a chip-on-glass (COG) or chip-on-panel (COP) method, or connected to the display panel 110 by a chip-on-film (COF) method. Alternatively, the gate driving circuit 120 may be formed in a non-display area NDA of the display panel 110 by a gate-in-panel (GIP) type. The gate driving circuit 120 may be disposed on or connected to the substrate. For example, the gate driving circuit 120 may be disposed in the non-display area NDA of the substrate if it is a GIP type. The gate driving circuit 120 may be connected to the substrate if it is a chip-on-glass (COG) type, a chip-on-film (COF) type, etc.

In addition, at least one of the data driving circuit 130 or the gate driving circuit 120 may be disposed in the display area DA of the display panel 110. For example, at least one of the data driving circuit 130 and the gate driving circuit 120 may be disposed so as not to overlap with the subpixels SP, or may be disposed so as to partially or completely overlap with the subpixels SP. The data driving circuit 130 may be connected to one side (e.g., the upper side or the lower side) of the display panel 110. Depending on the driving method, panel design method, etc., the data driving circuit 130 may be connected to both sides (e.g., the upper side and the lower side) of the display panel 110, or may be connected to two or more sides among the four sides of the display panel 110. The gate driving circuit 120 may be connected to one side (e.g., left or right) of the display panel 110. Depending on the driving method, panel design method, etc., the gate driving circuit 120 may be connected to both sides (e.g., left and right) of the display panel 110, or may be connected to two or more of the four sides of the display panel 110.

The display controller 140 may be implemented as a separate component from the data driving circuit 130, or may be implemented as an integrated circuit by being integrated with the data driving circuit 130. The display controller 140 may be a timing controller used in conventional display technology, or may be a control device capable of performing other control functions including a timing controller, or may be a control device other than the timing controller or a circuit within the control device. The display controller 140 may be implemented as various circuits or electronic components such as an integrated-circuit (IC), a field programmable gate array (FPGA), an application specific integrated-circuit (ASIC), or a processor. The display controller 140 may be mounted on a printed circuit board or a flexible printed circuit, and may be electrically connected to the data driving circuit 130 and the gate driving circuit 120 through the printed circuit board or the flexible printed circuit. The display controller 140 may transmit and receive signals with the data driving circuit 130 according to one or more predefined interfaces. Here, for example, the interface may include an LVDS (Low Voltage Differential Signaling) interface, an embedded clock point-point interface (EPI) interface, an SP (Serial Peripheral) interface, etc.

The display device 100 according to the examples of the present disclosure may include a touch sensor and a touch circuit that senses the touch sensor to detect an occurrence of a touch by a touch object such as a finger or a pen or detects a touch position in order to provide a touch sensing function in addition to an image display function. The touch circuit may include a touch driving circuit 160 that drives and senses the touch sensor to generate and output touch sensing data, and a touch controller 170 that detects a touch occurrence or a touch position using the touch sensing data. The touch sensor may include a plurality of touch electrodes. The touch sensor may further include a plurality of touch lines for electrically connecting a plurality of touch electrodes and a touch driving circuit 160. The touch sensor may be present in the form of a touch panel on the outside of the display panel 110, or may be present inside the display panel 110. If the touch sensor is present in the form of a touch panel on the outside of the display panel 110, the touch sensor may be referred to as an external type. If the touch sensor is an external type, the touch panel and the display panel 110 may be manufactured separately and combined during the assembly process. The external type touch panel may include a substrate for a touch panel and a plurality of touch electrodes on the substrate for the touch panel. If the touch sensor is present inside the display panel 110, the touch sensor may be formed on the substrate SUB together with signal lines and electrodes related to display driving during the manufacturing process of the display panel 110.

The touch driving circuit 160 may supply a touch driving signal to at least one of the plurality of touch electrodes and generate touch sensing data by sensing at least one of the plurality of touch electrodes. The touch circuit may perform touch sensing in a self-capacitance sensing manner or a mutual-capacitance sensing manner. If the touch circuit performs touch sensing in a self-capacitance sensing manner, the touch circuit may perform touch sensing based on the capacitance between each touch electrode and a touch object (e.g., a finger, a pen, etc.).

According to the self-capacitance sensing manner, each of the plurality of touch electrodes may act as a driving touch electrode and also act as a sensing touch electrode. The touch driving circuit 160 may drive all or part of the plurality of touch electrodes and sense all or part of the plurality of touch electrodes. If the touch circuit performs touch sensing in a mutual-capacitance sensing manner, the touch circuit may perform touch sensing based on the capacitance between the touch electrodes. According to the mutual-capacitance sensing manner, a plurality of touch electrodes may be divided into driving touch electrodes and sensing touch electrodes. The touch driving circuit 160 may drive the driving touch electrodes and sense the sensing touch electrodes. The touch driving circuit 160 and the touch controller 170 included in the touch circuit may be implemented as separate devices or as one device. In addition, the touch driving circuit 160 and the data driving circuit 130 may be implemented as separate devices or as one device.

The display device 100 may further include a power supply circuit that supplies various types of power to the display driving circuit and/or the touch circuit. The display device 100 according to the examples of the present disclosure may be a mobile terminal such as a smart phone or tablet, or a monitor or television (TV) of various sizes, and may be a display of various types and sizes capable of displaying information or images, without being limited thereto.

As described above, the display area DA in the display panel 110 may include a normal area NA and one or more optical areas OA1 and OA2. The normal area NA and one or more optical areas OA1 and OA2 may be areas capable of displaying images. However, the normal area NA may be an area where a light-transmitting structure is not formed, and the one or more optical areas OA1 and OA2 may be areas where a light-transmitting structure is formed. As described above, the display area DA in the display panel 110 may include one or more optical areas OA1 and OA2 together with the normal area NA, but for convenience of explanation, it is assumed that the display area DA includes both the first optical area OA1 and the second optical area OA2.

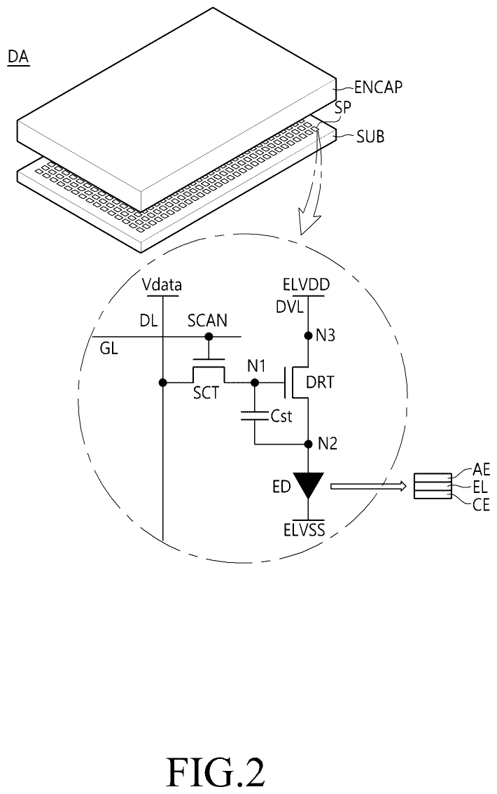

FIG. 2 illustrates an equivalent circuit of a subpixel SP in the display panel 110 according to examples of the present disclosure as an example.

Referring to FIG. 2, in the display panel 110 according to the examples of the present disclosure, each of the subpixels SP arranged in the normal area NA, the first optical area OA1, and the second optical area OA2 included in the display area DA may include a light emitting element ED, a driving transistor DRT for driving the light emitting element ED, a scan transistor SCT for transmitting a data voltage Vdata to a first node N1 of the driving transistor DRT, and a storage capacitor Cst for maintaining a constant voltage during one frame.

The driving transistor DRT may include a first node N1 to which a data voltage Vdata may be applied, a second node N2 electrically connected to the light emitting element ED, and a third node N3 to which a driving voltage ELVDD is applied from a driving voltage line DVL. In the driving transistor DRT, the first node N1 may be a gate node, the second node N2 may be a source node or a drain node, and the third node N3 may be a drain node or a source node.

The light emitting element ED may include an anode electrode AE, an emission layer EL, and a cathode electrode CE. The anode electrode AE may be a pixel electrode disposed in each subpixel SP and may be electrically connected to the second node N2 of the driving transistor DRT of each subpixel SP. The cathode electrode CE may be a common electrode arranged in common to a plurality of subpixels SP, and may be supplied with a base voltage ELVSS. For example, the anode electrode AE may be a pixel electrode, and the cathode electrode CE may be a common electrode. Alternatively, the anode electrode AE may be a common electrode, and the cathode electrode CE may be a pixel electrode. Hereinafter, for convenience of explanation, it is assumed that the anode electrode AE is a pixel electrode, and the cathode electrode CE is a common electrode, but the present disclosure is not limited thereto. For example, the light emitting element ED may be an organic light emitting diode (OLED), an inorganic light emitting diode, or a quantum dot light emitting element. In this case, if the light emitting element ED is an organic light emitting diode, the emission layer EL in the light emitting element ED may include an organic emission layer containing an organic material.

The scan transistor SCT may be turned on and off by a scan signal SCAN, which is a gate signal applied through a gate line GL, and may be electrically connected between the first node N1 of the driving transistor DRT and the data line DL. The storage capacitor Cst may be electrically connected between the first node N1 and the second node N2 of the driving transistor DRT. Each subpixel SP may have a 2T1C structure including two transistors (e.g., DRT and SCT) and one capacitor Cst as illustrated in FIG. 2, and may further include one or more transistors or one or more capacitors, depending on the case. For example, the subpixel may have a 8T1C structure including 8 transistors and 1 capacitor. As another example, the subpixel may have a 6T2C structure including 6 transistors and 2 capacitors. As another example, the subpixel may have a 7T1C structure including 7 transistors and 1 capacitor. The storage capacitor Cst may be an external capacitor intentionally designed outside the driving transistor DRT, rather than a parasitic capacitor (e.g., Cgs, Cgd) that may exist between the first node N1 and the second node N2 of the driving transistor DRT. Each of the driving transistor DRT and the scan transistor SCT may be an n-type transistor or a p-type transistor. Depending on the structure of the subpixel circuit SPC, the type and number of gate lines or the gate signals supplied to the subpixel SP may vary.

Since the circuit elements (particularly, the light emitting element ED) in each subpixel SP are vulnerable to external moisture or oxygen, an encapsulation layer ENCAP may be disposed on the display panel 110 to prevent or reduce external moisture or oxygen from penetrating into the circuit elements (particularly, the light emitting element ED). The encapsulation layer ENCAP may be disposed in a form that covers the light emitting elements ED.

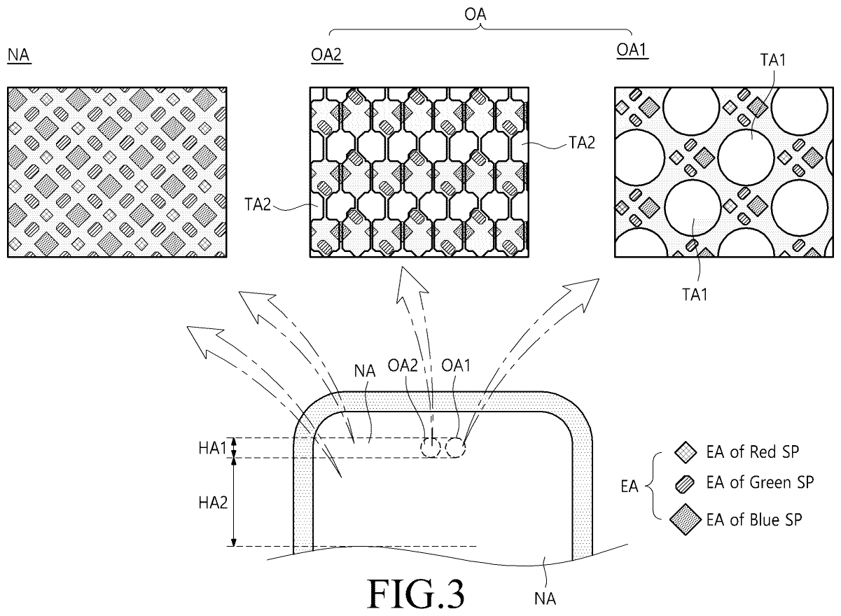

FIG. 3 illustrates the arrangement of subpixels SP in three areas included in the display area DA in the display panel 110 according to examples of the present disclosure.

Referring to FIG. 3, in the display panel 110 according to the examples of the present disclosure, the plurality of subpixels SP may be disposed in each of the normal area NA, the first optical area OA1, and the second optical area OA2 included in the display area DA.

The plurality of subpixels SP may include a red subpixel that emits red light, a green subpixel that emits green light, and a blue subpixel that emits blue light. Accordingly, each of the normal area NA, the first optical area OA1, and the second optical area OA2 may include emission areas EA of red subpixels, emission areas EA of green subpixels, and emission areas EA of blue subpixels. The normal area NA may not include a light-transmitting structure, but may include emission areas EA. However, the first optical area OA1 and the second optical area OA2 may include not only emission areas EA, but also light transmitting structures. Accordingly, the first optical area OA1 may include an emission area EA and a first transmission area TA1, and the second optical area OA2 may include an emission areas EA and a second transmission area TA2.

The emission areas EA and the transmission areas TA1 and TA2 can be distinguished based on whether light is transmitted. For example, the emission areas EA may be areas that are not light-transmissive, and the transmission areas TA1 and TA2 may be areas that are light-transmissive. In addition, the emission areas EA and the transmission areas TA1 and TA2 can be distinguished based on whether a specific metal layer is formed. For example, in a case that the specific metal layer is a cathode electrode CE, a cathode electrode CE may be formed in the emission areas EA, and a cathode electrode CE may not be formed in the transmission areas TA1 and TA2. For another example, in a case that the specific metal layer is a light shield layer, a light shield layer may be formed in the emission areas EA, and a light shield layer may not be formed in the transmission areas TA1 and TA2.

Since the first optical area OA1 includes the first transmission area TA1 and the second optical area OA2 includes the second transmission area TA2, both the first optical area OA1 and the second optical area OA2 are areas through which light can pass. The transmissivity (e.g., transmittance level) of the first optical area OA1 and the transmissivity of the second optical area OA2 may be the same. In this case, the first transmission area TA1 of the first optical area OA1 and the second transmission area TA2 of the second optical area OA2 may have the same shape or size. Alternatively, even if the first transmission area TA1 of the first optical area OA1 and the second transmission area TA2 of the second optical area OA2 have different shapes or sizes, the ratio of the first transmission area TA1 in the first optical area OA1 and the ratio of the second transmission area TA2 in the second optical area OA2 may be the same.

Alternatively, the transmissivity (e.g., transmittance degree or transmission level) of the first optical area OA1 and the transmissivity of the second optical area OA2 may be different from each other. In this case, the first transmission area TA1 of the first optical area OA1 and the second transmission area TA2 of the second optical area OA2 may have different shapes or sizes. Alternatively, even if the first transmission area TA1 of the first optical area OA1 and the second transmission area TA2 of the second optical area OA2 have the same shape or size, the ratio of the first transmission area TA1 in the first optical area OA1 and the ratio of the second transmission area TA2 in the second optical area OA2 may be different from each other. For example, if the first optical electronic device overlapping with the first optical area OA1 is a camera and the second optical electronic device overlapping with the second optical area OA2 is a detection sensor, the camera may involve a greater amount of light than the detection sensor. Therefore, the transmittance or transmissivity of the first optical area OA1 may be higher than the transmittance or transmissivity of the second optical area OA2. In this case, the first transmission area TA1 of the first optical area OA1 may have a larger size than the second transmission area TA2 of the second optical area OA2. Alternatively, even if the first transmission area TA1 of the first optical area OA1 and the second transmission area TA2 of the second optical area OA2 have the same size, the ratio of the first transmission area TA1 in the first optical area OA1 may be greater than the ratio of the second transmission area TA2 in the second optical area OA2.

Hereinafter, for convenience of explanation, it will be described as an example a case in which the transmittance or transmissivity of the first optical area OA1 is higher than the transmittance or transmissivity of the second optical area OA2. In addition, in the examples of the present disclosure, the transmission areas TA1 and TA2 may also be referred to as transparent areas, and the transmittance or transmissivity may also be referred to as transparency. In addition, in the examples of the present disclosure, it is assumed that the first optical area OA1 and the second optical area OA2 are located at the upper portion of the display area DA of the display panel 110 and are arranged side by side on the left and right.

The horizontal display area where the first optical area OA1 and the second optical area OA2 are disposed is referred to as a first horizontal display area HA1, and the horizontal display area where the first optical area OA1 and the second optical area OA2 are not disposed is referred to as a second horizontal display area HA2. The first horizontal display area HA1 may include a normal area NA, a first optical area OA1, and a second optical area OA2. The second horizontal display area HA2 may include only the normal area NA.

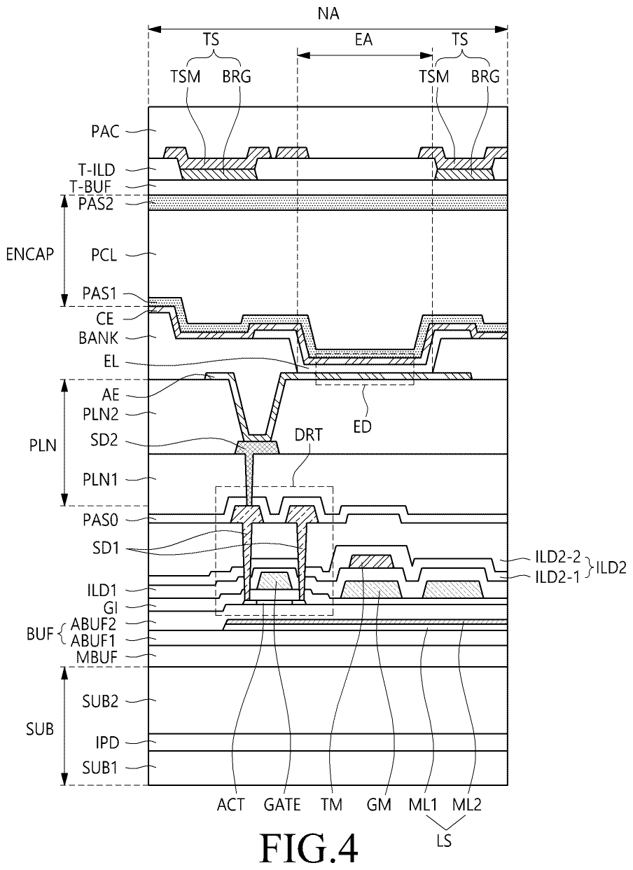

FIG. 4 illustrates an example of a cross-section of the display area DA in the display panel 110 according to examples of the present disclosure. Here, it is illustrated the normal area NA excluding the optical area OA where the optical electronic device is located.

Referring to FIG. 4, the display panel 110 according to examples of the present disclosure may include a substrate SUB, a driving transistor DRT, a planarization layer PLN, a light emitting element ED, an encapsulation layer ENCAP, and a touch layer.

The substrate SUB may include a first substrate SUB1, a substrate insulating film IPD, and a second substrate SUB2. The substrate insulating film IPD may be located between the first substrate SUB1 and the second substrate SUB2. The moisture penetration may be prevented or reduced by configuring the substrate SUB with a first substrate SUB1, a substrate insulating film IPD, and a second substrate SUB2. For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Various patterns (e.g., ACT, SD1 and GATE), various insulating films (e.g., MBUF, ABUF1, ABUF2, GI, ILD1, ILD2 and PAS0), and various metal patterns (e.g., TM, GM, ML1 and ML2) for forming transistors such as a driving transistor DRT may be disposed on the substrate SUB.

A multi-buffer layer MBUF may be disposed on the second substrate SUB2, and a first active buffer layer ABUF1 may be disposed on the multi-buffer layer MBUF. A first metal layer ML1 and a second metal layer ML2 may be disposed on the first active buffer layer ABUF1. Here, the first metal layer ML1 and the second metal layer ML2 may be a light shield layer LS for shielding the light. A second active buffer layer ABUF2 may be disposed on the first metal layer ML1 and the second metal layer ML2. An active layer ACT of a driving transistor DRT may be disposed on the second active buffer layer ABUF2. A gate insulating film GI may be disposed while covering the active layer ACT.

A gate electrode GATE of a driving transistor DRT may be disposed on the gate insulating film GI. In this case, at a position different from the formation position of the driving transistor DRT, a gate material layer GM may be disposed on the gate insulating film GI together with the gate electrode GATE of the driving transistor DRT.

A first interlayer insulating film ILD1 may be disposed while covering the gate electrode GATE and the gate material layer GM. A metal pattern TM may be disposed on the first interlayer insulating film ILD1. The metal pattern TM may be located at a position different from the formation position of the driving transistor DRT.

A second interlayer insulating film ILD2 may be disposed while covering the metal pattern TM on the first interlayer insulating film ILD1. Two first source-drain electrode patterns SD1 may be disposed on the second interlayer insulating film ILD2. One of the two first source-drain electrode patterns SD1 is a source node of a driving transistor DRT, and the other is a drain node of the driving transistor DRT. The two first source-drain electrode patterns SD1 may be electrically connected to one side and the other side of the active layer ACT, respectively, through contact holes of the second interlayer insulating film ILD2, the first interlayer insulating film ILD1, and the gate insulating film GI. In addition, the second interlayer insulating film ILD2 may include a 2-1 interlayer insulating film ILD2-1 and a 2-2 interlayer insulating film ILD2-2. The 2-1 interlayer insulating film ILD2-1 may be disposed while covering the metal pattern TM. The 2-2 interlayer insulating film ILD2-2 may be positioned on the 2-1 interlayer insulating film ILD2-1.

A portion of the active layer ACT overlapping with the gate electrode GATE may be a channel area. One of the two first source-drain electrode patterns SD1 may be connected to one side of the channel area in the active layer ACT, and the other of the two first source-drain electrode patterns SD1 may be connected to the other side of the channel area in the active layer ACT. A passivation layer PAS0 may be disposed while covering the two first source-drain electrode patterns SD1. A planarization layer PLN may be disposed on the passivation layer PAS0. The planarization layer PLN may include a first planarization layer PLN1 and a second planarization layer PLN2. The planarization layer PLN may be formed of an organic insulating material such as an acrylic resin. The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 (corresponding to the second node N2 of the driving transistor DRT in the subpixel SP of FIG. 3) through a contact hole of the first planarization layer PLN1. The second planarization layer PLN2 may be disposed while covering the second source-drain electrode pattern SD2. A light emitting element ED may be disposed on the second planarization layer PLN2.

The light emitting element ED may include an anode electrode AE, an emission layer EL, and a cathode electrode CE. The anode electrode AE may be disposed on the second planarization layer PLN2. The anode electrode AE may be electrically connected to the second source-drain electrode pattern SD2 through a contact hole of the second planarization layer PLN2. The bank BANK may be disposed while covering a part of the anode electrode AE. A part of the bank BANK corresponding to the emission area EA of the subpixel SP may be opened or removed. A part of the anode electrode AE may be exposed to an opening (or open portion) of the bank BANK. An emission layer EL may be located on the side of the bank BANK and the opening (or open portion) of the bank BANK. All or part of the emission layer EL may be located between adjacent banks BANK. The emission layer EL may include an organic film. In the opening of the bank BANK, the emission layer EL may be in contact with the anode electrode AE. A cathode electrode CE may be disposed on the emission layer EL.

An encapsulation layer ENCAP may be disposed on the light emitting element ED. The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2. For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest. Accordingly, the second encapsulation layer PCL may function as a planarization layer.

The first encapsulation layer PAS1 may also be referred to as a first inorganic encapsulation layer, the second encapsulation layer PCL may also be referred to as an organic encapsulation layer, and the third encapsulation layer PAS2 may also be referred to as a second inorganic encapsulation layer. The first encapsulation layer PAS1 may be disposed on the cathode electrode CE and may be disposed closest to the light emitting element ED. The first encapsulation layer PAS1 may be formed of an inorganic insulating material capable of low-temperature deposition. For example, the first encapsulation layer PAS1 may be silicon nitride (SiNx), silicon oxide (SiOx), silicon oxynitride (SiON), or aluminum oxide (Al2O3). Since the first encapsulation layer PAS1 is deposited in a low-temperature atmosphere, the first encapsulation layer PAS1 may prevent or reduce the emission layer EL including an organic material vulnerable to a high-temperature atmosphere from being damaged during the deposition process.

The second encapsulation layer PCL may be formed with a smaller area than the first encapsulation layer PAS1. In this case, the second encapsulation layer PCL may be formed to expose both ends of the first encapsulation layer PAS1. The second encapsulating layer PCL may act as a buffer to relieve stress between each layer due to bending of the display device 100, and may also serve to enhance flattening performance. For example, the second encapsulation layer PCL may be formed of an acrylic resin, an epoxy resin, a polyimide, polyethylene, or silicon oxycarbon (SiOC), and may be formed of an organic insulating material. For example, the second encapsulation layer PCL may be formed through an inkjet method.

The third encapsulation layer PAS2 may be formed on the second encapsulation layer PCL to cover the upper surface and side surfaces of each of the second encapsulation layer PCL and the first encapsulation layer PAS1. The third encapsulation layer PAS2 may reduce, minimize or block external moisture or oxygen from penetrating into the first encapsulation layer PAS1 and the second encapsulation layer PCL. For example, the third encapsulation layer PAS2 may be formed of an inorganic insulating material such as silicon nitride (SiNx), silicon oxide (SiOx), silicon oxynitride (SiON), or aluminum oxide (Al2O3).

In addition, the display device 100 of the present disclosure may have a touch sensor TS formed on the encapsulation layer ENCAP to detect a touch of a user's finger or pen. If the touch sensor TS is of a type built into the display panel 110, the touch sensor TS may be disposed on the encapsulation layer ENCAP. It will be described the touch sensor structure in detail as follows. A touch buffer film T-BUF may be disposed on the encapsulation layer ENCAP. A touch sensor TS may be disposed on the touch buffer film T-BUF. The touch sensor TS may include a touch sensor metal TSM and a bridge metal BRG positioned in different layers. The touch sensor metal TSM and the bridge metal BRG may be formed of a triple structure of Ti/Al/Ti.

A touch interlayer insulating film T-ILD may be disposed between the touch sensor metal TSM and the bridge metal BRG. The touch interlayer insulating film T-ILD may be formed of an inorganic material such as silicon nitride (SiNx) or silicon oxide (SiOx). In this case, the touch interlayer insulating film T-ILD may be formed of an inorganic material such as silicon oxide (SiOx) to improve touch performance. For example, the touch sensor TS may include a first touch sensor metal, a second touch sensor metal, and a third touch sensor metal that are positioned adjacent to each other. If a third touch sensor metal is present between the first touch sensor metal and the second touch sensor metal, and the first touch sensor metal and the second touch sensor metal are to be electrically connected to each other, the first touch sensor metal and the second touch sensor metal may be electrically connected to each other through a bridge metal BRG in a different layer. The bridge metal BRG may be insulated from the third touch sensor metal by a touch interlayer insulating film T-ILD.

When a touch sensor TS is formed on the display panel 110, a chemical solution (e.g., developer solution or etchant, etc.) used in the process or moisture may be generated from the outside. Since the touch sensor TS is disposed on a touch buffer film T-BUF, the chemical solution or moisture may be prevented or reduced from penetrating into the emission layer EL including an organic substance during the manufacturing process of the touch sensor TS. Accordingly, the touch buffer film T-BUF may prevent or reduce damage to the emission layer EL that is vulnerable to liquid or moisture. The touch buffer film T-BUF may be formed at a low temperature (e.g., 100° C.) or lower, and may be formed of an organic insulating material having a low dielectric constant in order to prevent or reduce damage to the emission layer EL including an organic material vulnerable to high temperatures. For example, the touch buffer film T-BUF may be formed of an acrylic series, an epoxy series, or a siloxane series material.

If the display device 100 is bent, the encapsulation layer ENCAP may be damaged due to bending, and the touch sensor metal TSM located on the touch buffer film T-BUF may be broken. Even if the display device 100 is bent, the encapsulation layer ENCAP may be prevented or reduced from being damaged or the touch sensor metal TSM or bridge metal BRG may be prevented or reduced from being broken by the touch buffer film T-BUF having flattening performance using an organic insulating material.

A protection layer PAC can be arranged while covering the touch sensor TS. The protective layer PAC can be an organic insulating film.

In the display panel 110, the light emitting element ED may be damaged by moisture flowing into the emission layer EL through a through-hole TH. In addition, moisture generated during the process of forming the touch sensor TS or flowing in from the outside may flow into the encapsulation layer ENCAP through the upper touch interlayer insulating film T-ILD and the touch buffer film T-BUF to damage the light emitting element ED. The display panel 110 of the present disclosure may block moisture from flowing in through the through-hole TH by forming an emission layer disconnection pattern that disconnects the emission layer EL between the through-hole TH and the normal area NA.

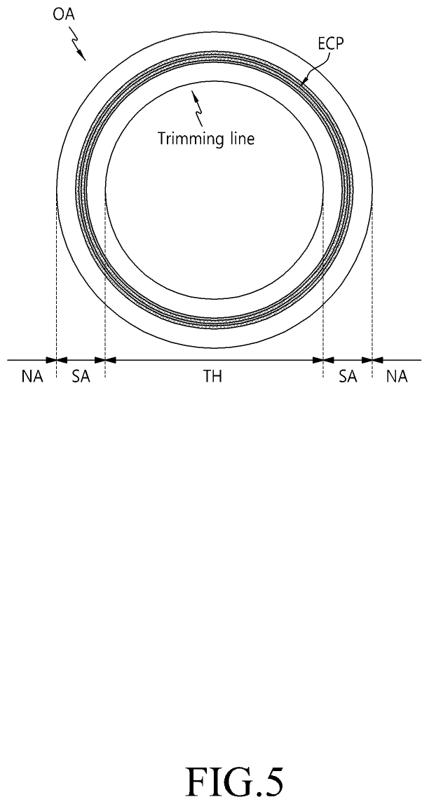

FIG. 5 illustrates a planar structure of an optical area OA in the display panel 110 according to examples of the present disclosure.

Referring to FIG. 5, the display panel 110 according to the examples of the present disclosure may include an optical area OA within a display area DA. The optical area OA may be one of the first optical area OA1 or the second optical area OA2 described above. The optical area OA may include the through-hole TH and a surrounding area SA around the through-hole TH. An emission layer disconnection pattern ECP for preventing or reducing moisture permeation may be positioned in the surrounding area SA. The through-hole TH may be formed by removing the substrate along a trimming line. The shape of the through-hole TH may be circular, but may have various shapes such as an oval, a square, a hexagon, or an octagon.

The emission layer disconnection pattern ECP may include one or more patterns in the surrounding area SA to block a moisture permeation path along the emission layer EL. In addition, an inner dam may be additionally formed between the emission layer disconnection pattern ECP and the through-hole TH to separate the emission layer disconnection pattern ECP and the through-hole TH. An outer dam (not shown) may be further positioned outside a first emission layer disconnection pattern ECP1 in the normal area NA. The outer dam may be disposed to prevent or reduce the encapsulation layer ENCAP from overflowing outside the normal area NA. The emission layer disconnection pattern ECP may have a closed curve shape that corresponds to the shape of the through-hole TH and surrounds the through-hole TH. The emission layer disconnection pattern ECP may have a closed curve shape different from the through-hole TH, but may have a closed curve shape with the same shape but different sizes. Here, it is exemplified a case in which the emission layer disconnection pattern ECP and the through-hole TH have the same shape and are arranged at a certain interval.

The optical area OA may include the through-hole TH and the surrounding area SA, and the normal area NA may be located on the outside of the surrounding area SA. An optical electronic device 11 may be located in the through-hole TH below the display panel 110, and the optical electronic device 11 may be disposed to overlap with at least a portion of the through-hole TH.

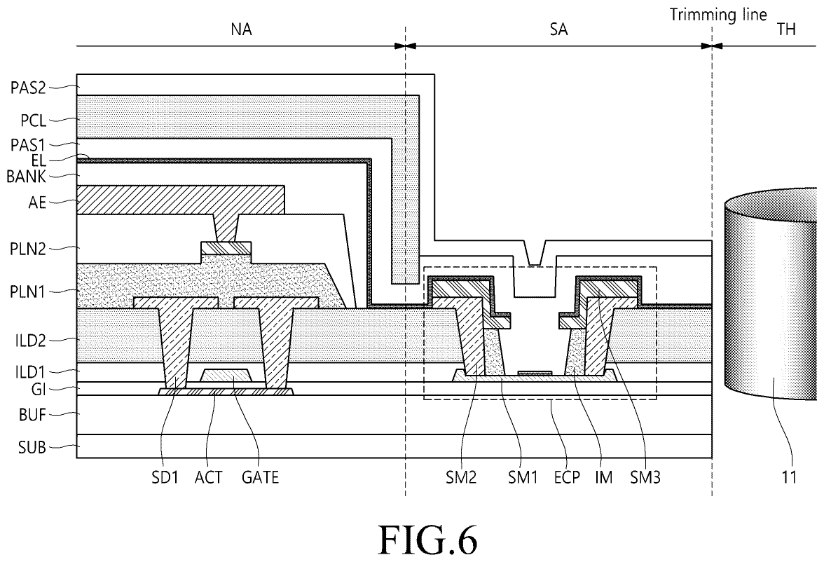

FIG. 6 is a cross-sectional view of the normal area NA and the optical area OA in the display panel 110 according to examples of the present disclosure.

Referring to FIG. 6, the display panel 110 according to the examples of the present disclosure may include the emission layer disconnection pattern ECP to prevent or reduce moisture from flowing from the through-hole TH where an optical electronic device 11 is located to the normal area NA where a subpixel SP is formed.

The emission layer disconnection pattern ECP may be formed at least once between the through-hole TH and the normal area NA. The emission layer disconnection pattern ECP may include the sidewall structures (e.g., two sidewall structures) and a recessed area that is recessed between the sidewall structures while separating the sidewall structures. The emission layer EL formed in the optical area OA may be physically divided into an emission layer located on the sidewall structure and an emission layer located on the recessed area by the recessed area of the emission layer disconnection pattern ECP. For example, as shown in FIG. 6, the emission layer located on the sidewall structure and the emission layer located on the recessed area are spaced apart and electrically separated from each other by the recessed area of the emission layer disconnection pattern ECP. Therefore, moisture flowing in through the through-hole TH can be blocked from being transmitted to the normal area NA by the recessed area of the emission layer disconnection pattern ECP.

In this case, the emission layer disconnection pattern ECP may include a first shielding layer SM1 for preventing or reducing moisture penetration in the lower direction, a second shielding layer SM2 for preventing or reducing moisture penetration in the side direction, and a third shielding layer SM3 for preventing or reducing moisture penetration in the upper direction. The first shielding layer SM1 may be formed of the same material as a gate electrode GATE constituting a transistor of the normal area NA. For example, the first shielding layer SM1 may be formed of titanium (Ti). In addition, the first shielding layer SM1 may have a protrusion formed on the outer surface thereof so as to support the second shielding layer SM2. The second shielding layer SM2 may be formed of the same material as a first source-drain electrode pattern SD1 constituting a transistor of the normal area NA. The second shielding layer SM2 may be formed of a laminated metal structure of titanium/aluminum/titanium (Ti/Al/Ti). The third shielding layer SM3 may be formed of the same material as a second source-drain electrode pattern SD2 constituting a transistor of the normal area NA. The third shielding layer SM3 may be formed of a laminated metal structure of titanium/aluminum/titanium (Ti/Al/Ti).

In addition, the emission layer disconnection pattern ECP may include a disconnection insulating layer IM of an undercut structure formed on the inner side of the second shielding layer SM2 and the lower side of the third shielding layer SM3 for effective disconnection insulation of the emission layer EL. The disconnection insulating layer IM may be formed of the same material as the first planarization layer PLN1 of the normal area NA. In this case, the outer side of the emission layer disconnection pattern ECP may be formed of a double-layered structure of the first interlayer insulating film ILD1 and the second interlayer insulating film ILD2. In this case, the first interlayer insulating film ILD1 may be formed of an inorganic material such as silicon oxide or silicon nitride, and the second interlayer insulating film ILD2 on the upper side of the first interlayer insulating film ILD1 may be formed of an organic material.

Since the through-hole TH where the optical electronic device 11 is located is adjacent to the outer area of the display panel 110, flexible characteristics may be involved. In this case, since the inorganic interlayer insulating film is vulnerable to flexible characteristics, and there is a risk of having conductivity if the thickness thereof is large, so there is a limitation on the thickness of the inorganic interlayer insulating film. Therefore, by forming the first interlayer insulating film ILD1 with an inorganic material and laminating the second interlayer insulating film ILD2 with a thickness greater than that of the first interlayer insulating film ILD1, flexible characteristics can be effectively secured. The thickness of the second interlayer insulating film ILD2 with an organic material may be 1 to 5 times greater than that of the first interlayer insulating film ILD1 with an inorganic material, thereby improving flexible characteristics and preventing or reducing conductivity defect. In this way, the display panel 110 of the present disclosure may improve the moisture blocking effect and flexible characteristics through the emission layer disconnection pattern ECP formed along the surrounding area SA outside the through-hole TH.

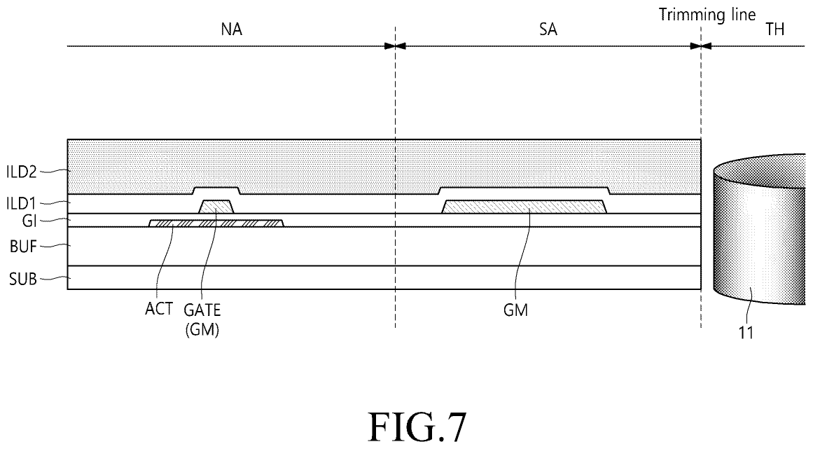

FIGS. 7-13 are cross-sectional views sequentially illustrating a manufacturing process of the display panel 110 according to examples of the present disclosure.

First, referring to FIG. 7, in the display panel 110 according to examples of the present disclosure, a buffer layer BUF may be formed on a substrate SUB. The substrate SUB may include a first substrate, a substrate insulating film, and a second substrate, and the substrate insulating film may be positioned between the first substrate and the second substrate. An active layer ACT for forming a transistor such as a driving transistor DRT may be disposed on the buffer layer BUF. A gate insulating film GI may be disposed while covering the active layer ACT. A gate electrode GATE of the driving transistor DRT may be disposed on the gate insulating film GI of the normal area NA. In this case, a gate material layer GM of the same material as the gate electrode GATE may be disposed on the gate insulating film GI in the surrounding area SA of the through-hole TH. The gate material layer GM of the surrounding area SA may be a layer for forming a first shielding layer SM1 to prevent or reduce moisture penetration in the downward direction.

A first interlayer insulating film ILD1 may be disposed to cover the gate electrode GATE of the normal area NA and the gate material layer GM of the surrounding area SA. In addition, a second interlayer insulating film ILD2 may be disposed on the first interlayer insulating film ILD1. In this case, the first interlayer insulating film ILD1 may be made of an inorganic material such as silicon oxide or silicon nitride, and the second interlayer insulating film ILD2 may be made of an organic material. Since the through-hole TH where the optical electronic device 11 is located is adjacent to the outer area of the display panel 110, flexible characteristics may be involved. In this case, the inorganic interlayer insulating film is vulnerable to flexible characteristics, and there is a risk of exhibiting conductivity if the thickness thereof is excessively large, so there is a limitation on the thickness. Therefore, by forming the thickness of the second interlayer insulating film ILD2 of the organic material to be greater than the thickness of the first interlayer insulating film ILD1 of the inorganic material, the flexible characteristic can be effectively secured. The thickness of the second interlayer insulating film ILD2 of the organic material may be formed to be 1 to 5 times greater than the thickness of the first interlayer insulating film ILD1 of the inorganic material.

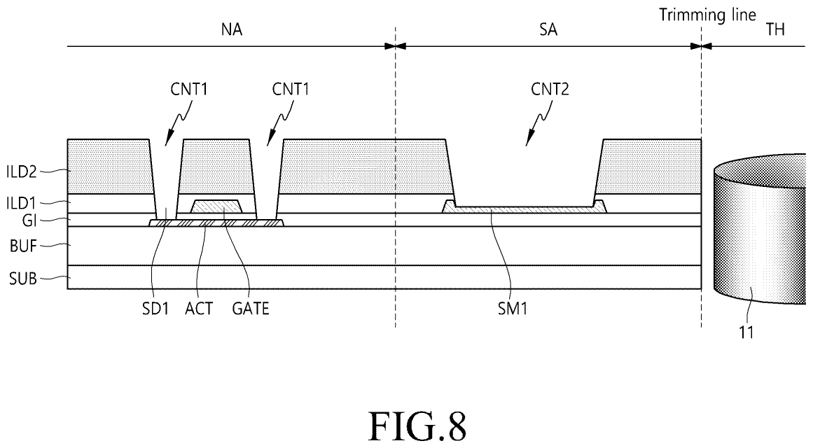

Referring to FIG. 8, a part of the first interlayer insulating film ILD1 and the second interlayer insulating film ILD2 may be etched to form contact holes CNT1 and CNT2. A first contact hole CNT1 may be a contact hole for forming a first source-drain electrode pattern SD1 that contacts the active layer ACT in the normal area NA. In addition, a second contact hole CNT2 may be a contact hole for forming a second shielding layer SM2 on the first shielding layer SM1 in the surrounding area SA. In this case, a part of the gate material layer GM may be etched together during the process of forming the second contact hole CNT2 in the surrounding area SA. As a result, the first shielding layer SM1 may be formed with a structure in which both ends protrude upward. The first shielding layer SM1 with both ends protruding upward may support the second shielding layer SM2 formed thereon, and may effectively block moisture from leaking from the contact portion with the second shielding layer SM2.

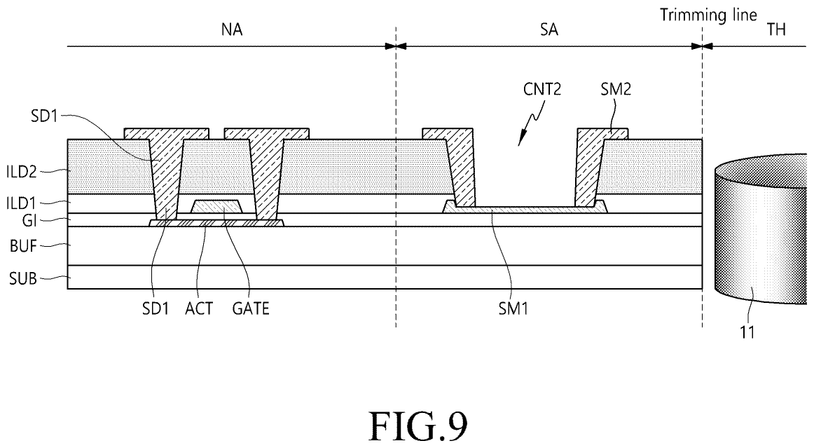

Referring to FIG. 9, a first source-drain electrode pattern SD1 may be formed on the second interlayer insulating film ILD2 to fill the first contact hole CNT1 of the normal area NA. One of the two first source-drain electrode patterns SD1 may be a source electrode of the driving transistor DRT, and the other may be a drain electrode of the driving transistor DRT. The two first source-drain electrode patterns SD1 may be electrically connected to one side and the other side of the active layer ACT through a first contact hole CNT1 of the second interlayer insulating film ILD2, the first interlayer insulating film ILD1, and the gate insulating film GI.

A portion of the active layer ACT overlapping with the gate electrode GATE may be a channel area. One of the two first source-drain electrode patterns SD1 may be connected to one side of the channel area in the active layer ACT, and the other of the two first source-drain electrode patterns SD1 may be connected to the other side of the channel area in the active layer ACT. In addition, a second shielding layer SM2 may be formed in the surrounding area SA to contact a part of the first shielding layer SM1 through a second contact hole CNT2. The first source-drain electrode pattern SD1 and the second shielding layer SM2 may be formed by applying a first source-drain material on the second interlayer insulating film ILD2 and performing an etching process. Therefore, the second shielding layer SM2 may be formed using the same material as the first source-drain electrode pattern SD1 and in the same process. In this case, the second shielding layer SM2 may be formed with a structure in which the central portion is open by the second contact hole CNT2.

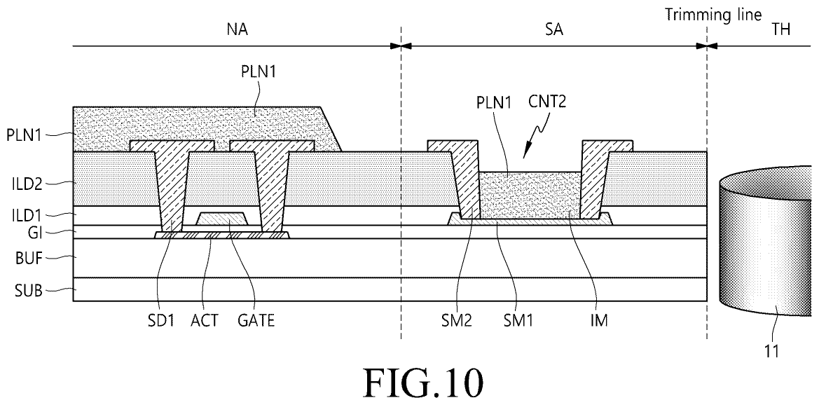

Referring to FIG. 10, a first planarization layer PLN1 may be disposed to cover the first source-drain electrode pattern SD1 and the second contact hole CNT2. The first planarization layer PLN1 is disposed to cover the first source-drain electrode pattern SD1 in the normal area NA. In addition, the first planarization layer PLN1 may be disposed inside the second contact hole CNT2 to cover the first shielding layer SM1 in the surrounding area SA.

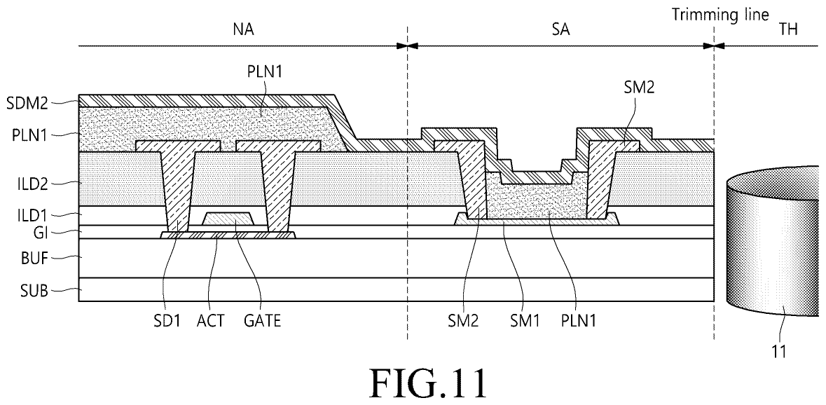

Referring to FIG. 11, a second source-drain material SDM2 may be applied to cover the first planarization layer PLN1 in the normal area NA and the surrounding area SA. The second source-drain material SDM2 is a metal material for forming the second source-drain electrode pattern SD2 in the normal area NA and forming the third shielding layer SM3 in the surrounding area SA.

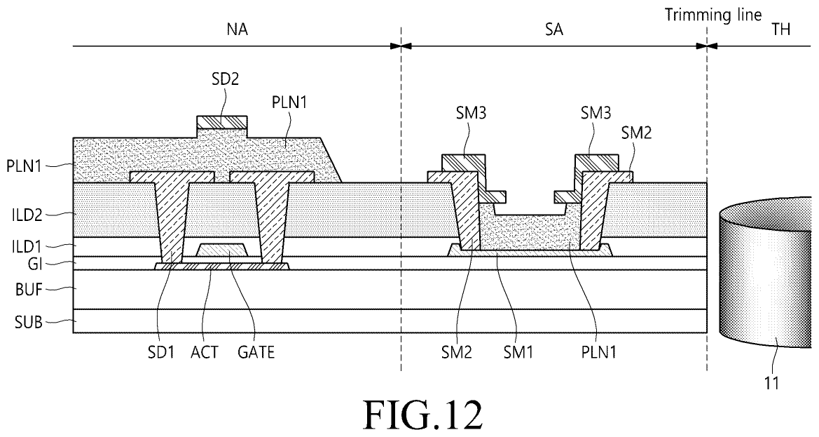

Referring to FIG. 12, a part of the second source-drain material SDM2 may be etched in the normal area NA to form a second source-drain electrode pattern SD2. The second source-drain electrode pattern SD2 may be connected to one of the first source-drain electrode patterns SD1 through a contact hole of the first planarization layer PLN1. In addition, a part of the second source-drain material SDM2 may be etched in the surrounding area SA to form a third shielding layer SM3. In the surrounding area SA, the third shielding layer SM3 may be formed on the second interlayer insulating film ILD2, and may be located at a portion where the second shielding layer SM2 is folded. In this case, in the process of etching the second source-drain material SDM2 to form the third shielding layer SM3, the first planarization layer PLN1 under the third shielding layer SM3 may be partially etched. As a result, the third shielding layer SM3 may protrude into an inner groove on the upper portion of the first planarization layer PLN1, and the first planarization layer PLN1 may support the upper third shielding layer SM3, so that the third shielding layer SM3 and the first planarization layer PLN1 form an undercut structure. In this way, the emission layer disconnection pattern ECP formed in the surrounding area SA may include a first shielding layer SM1 for preventing or reducing moisture penetration in a downward direction, a second shielding layer SM2 for preventing or reducing moisture penetration in a lateral direction, and a third shielding layer SM3 for preventing or reducing moisture penetration in an upward direction.

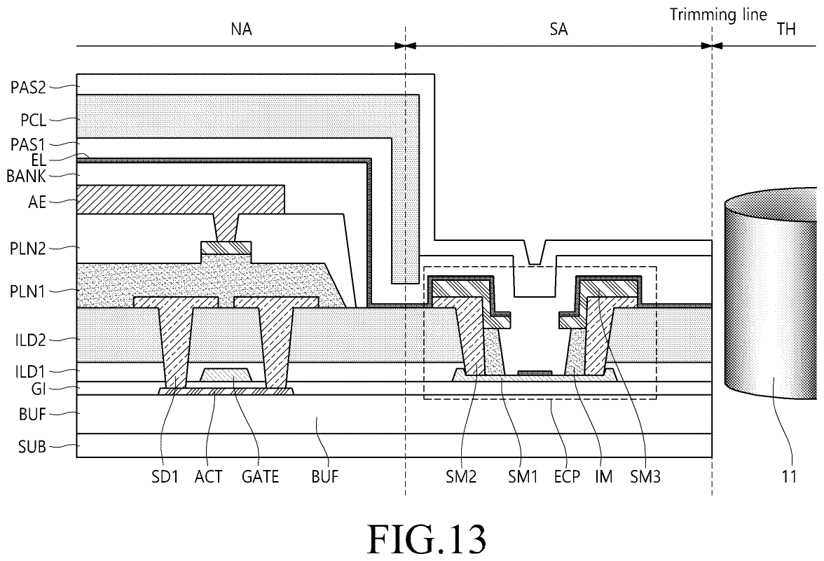

Referring to FIG. 13, when the surface is subjected to ashing while the second source-drain electrode pattern SD2 and the third shielding layer SM3 are formed, the first planarization layer PLN1 in the area where the third shielding layer SM3 is open may be removed. As a result, the first planarization layer PLN1 remaining under the third shielding layer SM3 may be formed as a disconnection insulating layer IM that insulates the second shielding layer SM2 under the third shielding layer SM3. In this case, the disconnection insulating layer IM may support the third shielding layer SM3 on top, thereby forming an undercut structure of the third shielding layer SM3. As a result, due to the undercut structure of the third shielding layer SM3 and the disconnection insulating layer IM, the emission layer formed on the third shielding layer SM3 and the emission layer formed inside the disconnection insulating layer IM may be effectively disconnected or separated. Thereafter, a second planarization layer PLN2 may be disposed while covering the second source-drain electrode pattern SD2. The light emitting element ED may be disposed on the second planarization layer PLN2.

The light emitting element ED may include an anode electrode AE, an emission layer EL, and a cathode electrode CE. The anode electrode AE may be disposed on the second planarization layer PLN2. The anode electrode AE may be electrically connected to the second source-drain electrode pattern SD2 through a contact hole of the second planarization layer PLN2.

A bank BANK may be disposed while covering a part of the anode electrode AE. A part of the bank BANK corresponding to the emission area EA of the subpixel SP may be opened. A part of the anode electrode AE may be exposed to an opening (or open portion) of the bank BANK. The emission layer EL may be located on the side of the bank BANK and in the opening (or open portion) of the bank BANK. All or a part of the emission layer EL may be located between adjacent banks BANK. The emission layer EL may include an organic film. In the opening of the bank BANK, the emission layer EL may be in contact with the anode electrode AE. A cathode electrode CE may be disposed on the emission layer EL.

An encapsulation layer ENCAP may be disposed on the light emitting element ED. The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2. For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest. Accordingly, the second encapsulation layer PCL may serve as a planarization layer. In addition, the display device 100 of the present disclosure may have a touch sensor TS formed on the encapsulation layer ENCAP to detect the touch of a user's finger or pen.

In this way, the display panel 110 of the present disclosure may improve the moisture-proof effect and flexible characteristics through the emission layer disconnection pattern ECP formed along the surrounding area SA outside the through-hole TH. It is to be noted that although one emission layer disconnection pattern ECP is shown in FIGS. 7-13 in the surrounding area SA between the normal area NA and the through hole TH, but the numbers and/or shape of the emission layer disconnection pattern ECP arranged in the surrounding area SA are not limited thereto. For example, two or more emission layer disconnection patterns may be arranged in the surrounding area SA, and the shape of each emission layer disconnection pattern is not limited to a circular shape, but may have various shapes such as an oval, a square, a hexagon, or an octagon.

The examples of the present disclosure described above are summarized as follows.

A display device according to the examples of the present disclosure may include a display panel in which an optical electronic device is disposed within a display area. In addition, the display area may include a normal area in which a plurality of subpixels including an emission layer are disposed, a through-hole in which the optical electronic device is located, and a surrounding area in which one or more emission layer disconnection patterns are formed between the normal area and the through-hole.

The surrounding area may include a substrate, a buffer layer formed on the substrate, a gate insulating film formed on the buffer layer, a first interlayer insulating film formed on the gate insulating film with a first thickness, a second interlayer insulating film formed on the first interlayer insulating film with a second thickness greater than the first thickness, and the one or more emission layer disconnection patterns formed on the gate insulating film in a contact hole where the first interlayer insulating film and the second interlayer insulating film are removed.

The first interlayer insulating film may be an inorganic material, and the second interlayer insulating film may be an organic material. The second thickness may be formed to be 1 to 5 times the first thickness.

The emission layer disconnection pattern may include a first shielding layer formed on the gate insulating film, a second shielding layer formed along an inner wall of the first interlayer insulating film and the second interlayer insulating film on the first shielding layer, a third shielding layer formed on the second shielding layer, and a disconnection insulating layer formed along an inner wall of the second shielding layer below the third shielding layer.

The first shielding layer may be formed of the same material as a gate electrode of the normal area.

The first shielding layer may be formed with a structure in which both ends protrude upward.

The second shielding layer may be formed of the same material as a first source-drain electrode pattern of the normal area.

The first source-drain electrode pattern may form a source electrode and a drain electrode of a driving transistor.

The third shielding layer may be formed of the same material as a second source-drain electrode pattern of the normal area.

The second source-drain electrode pattern may be a metal that connects the first source-drain electrode pattern and a light emitting element.

The disconnection insulating layer may be formed of the same material as a planarization layer of the normal area.

The disconnection insulating layer may be formed in an undercut structure under the third shielding layer.

A display panel according to examples of the present disclosure may include a normal area in which a plurality of subpixels including an emission layer are disposed, a through-hole in which an optical electronic device is located, and a surrounding area in which one or more emission layer disconnection patterns are formed between the normal area and the through-hole.

A display device according to examples of the present disclosure may include a display panel including a display area, wherein the display area comprises: a normal area in which a plurality of subpixels including an emission layer are disposed; a through-hole; and a surrounding area between the normal area and the through-hole, and wherein the emission layer is physically divided into two parts spaced apart from each other in the surrounding area.

The above description has been presented to enable a person skilled in the art to make and use the technical idea of the present disclosure, and has been provided in the context of a particular application. Various modifications, additions and substitutions to the described examples will be readily apparent to those skilled in the art, and the general principles described herein may be applied to other examples and applications without departing from the technical concept and scope of the present disclosure.

What is claimed is:

1. A display device, comprising:
a display panel including a display area, wherein the display area comprises:
a normal area in which a plurality of subpixels including an emission layer are disposed;
a through-hole; and
a surrounding area in which one or more emission layer disconnection patterns are formed between the normal area and the through-hole.

2. The display device of claim 1, wherein the surrounding area includes:
a substrate;
a buffer layer formed on the substrate;
a gate insulating film formed on the buffer layer;
a first interlayer insulating film formed on the gate insulating film with a first thickness;
a second interlayer insulating film formed on the first interlayer insulating film with a second thickness greater than the first thickness; and
the one or more emission layer disconnection patterns formed on the gate insulating film in a contact hole where the first interlayer insulating film and the second interlayer insulating film are removed.

3. The display device of claim 2, wherein the first interlayer insulating film is an inorganic material and the second interlayer insulating film is an organic material, and wherein the second thickness is formed to be 1 to 5 times the first thickness.

4. The display device of claim 2, wherein the one or more emission layer disconnection patterns include:
a first shielding layer formed on the gate insulating film;
a second shielding layer formed along an inner wall of the first interlayer insulating film and the second interlayer insulating film on the first shielding layer;
a third shielding layer formed on the second shielding layer; and
a disconnection insulating layer formed along an inner wall of the second shielding layer below the third shielding layer.

5. The display device of claim 4, wherein the first shielding layer is formed of the same material as a gate electrode of the normal area.

6. The display device of claim 4, wherein the first shielding layer is formed with a structure in which both ends protrude upward.

7. The display device of claim 4, wherein the second shielding layer is formed of the same material as a first source-drain electrode pattern of the normal area.

8. The display device of claim 7, wherein the first source-drain electrode pattern forms a source electrode and a drain electrode of a driving transistor.

9. The display device of claim 7, wherein the third shielding layer is formed of the same material as a second source-drain electrode pattern of the normal area.

10. The display device of claim 9, wherein the second source-drain electrode pattern is a metal that connects the first source-drain electrode pattern and a light emitting element.

11. The display device of claim 4, wherein the disconnection insulating layer is formed of the same material as a planarization layer of the normal area.

12. The display device of claim 4, wherein the third shielding layer protrudes into an inner groove on the disconnection insulating layer and is formed as an undercut structure with respect to the disconnection insulating layer.

13. The display device of claim 1, further comprising an optical electronic device disposed in the through-hole.

14. A display panel, comprising:
a normal area in which a plurality of subpixels including an emission layer are disposed;
a through-hole; and
a surrounding area in which one or more emission layer disconnection patterns are formed between the normal area and the through-hole.

15. The display panel of claim 14, wherein the surrounding area includes:
a substrate;
a buffer layer formed on the substrate;
a gate insulating film formed on the buffer layer;
a first interlayer insulating film formed on the gate insulating film with a first thickness;
a second interlayer insulating film formed on the first interlayer insulating film with a second thickness greater than the first thickness; and
the one or more emission layer disconnection patterns formed on the gate insulating film in a contact hole where the first interlayer insulating film and the second interlayer insulating film are removed.

16. The display panel of claim 15, wherein the one or more emission layer disconnection patterns include:
a first shielding layer formed on the gate insulating film;
a second shielding layer formed along an inner wall of the first interlayer insulating film and the second interlayer insulating film on the first shielding layer;
a third shielding layer formed on the second shielding layer; and
a disconnection insulating layer formed along an inner wall of the second shielding layer below the third shielding layer.

17. The display panel of claim 14, further comprising an optical electronic device disposed in the through-hole.

18. The display panel of claim 14, wherein each of the one or more emission layer disconnection patterns includes sidewall structures and a recessed area recessed between the sidewall structures.

19. A display device, comprising:
a display panel in which an optical electronic device is disposed within a display area, wherein the display area comprises:
a normal area in which a plurality of subpixels including an emission layer are disposed;
a through-hole in which the optical electronic device is positioned; and
a surrounding area in which one or more emission layer disconnection patterns are formed between the normal area and the through-hole.

20. A display device, comprising:
a display panel including a display area, wherein the display area comprises:
a normal area in which a plurality of subpixels including an emission layer are disposed;
a through-hole; and
a surrounding area between the normal area and the through-hole, and
wherein the emission layer is physically divided into two parts spaced apart from each other in the surrounding area.
